(19) United States
(12) Patent Application Publication
(10) Pub. No.: US 2025/0298053 A1
(43) Pub. Date: Sep. 25, 2025

(54) CONDUCTIVE PIN AND ELECTRONIC DEVICE TEST SOCKET EQUIPPED WITH SAME

(71) Applicant: MEGATOUCH CO., LTD., Cheonan-si (KR)

(72) Inventors: Tae-Yeong RYU, Gwangju (KR); Hae Joong MOON, Seoul (KR); Chi-Hun IN, Cheonan-si (KR)

(73) Assignee: MEGATOUCH CO., LTD., Cheonan-si (KR)

(21) Appl. No.: 18/893,989

(22) Filed: Sep. 24, 2024

(30) Foreign Application Priority Data
Mar. 20, 2024 (KR) 10-2024-0038388

(51) Int. Cl. G01R 1/067

(52) U.S. Cl. CPC G01R 1/06722; G01R 1/06738

(57) ABSTRACT

A conductive pin includes a first contact part capable of contacting a first electronic device, a second contact part capable of contacting a second electronic device, a connection part configured to connect the first contact part and the second contact part and to have an empty internal space, and in which at least some sections thereof are elastic, and an extension bar bent from the first contact part and extended through the internal space of the connection part toward the second contact part.

### CROSS REFERENCE TO RELATED APPLICATION

The present application claims priority to Korean Patent Application No. 10-2024-0038388 (filed on Mar. 20, 2024), which is hereby incorporated by reference in its entirety.

### BACKGROUND

The present disclosure relates to a conductive pin, and an electronic device test socket equipped with the conductive pin.

Generally, a stable electrical connection between a semiconductor device and test equipment needs to be established to test the electrical characteristics of electronic devices such as semiconductor devices. For electrical connection between semiconductor devices and test equipment, test sockets are used.

A typical test socket includes multiple pogo pins.

FIG. 1 shows a cross-sectional view of a pogo pin 100 according to a conventional embodiment.

The pogo pin 100 is used to facilitate the connection between semiconductor devices and test equipment, and is used in most test sockets due to its mechanical shock relief and electrical characteristics.

The pogo pin 100 is usually made of a metal material, and a spring s is inserted along with at least one of two plungers p1 and p2 inside a barrel 110 to support the plungers p1 and p2. Accordingly, the plungers p1 and p2 receive force from the spring s in opposite directions.

However, the plungers p1 and p2 are often cut into three-dimensional shapes, making precision machining difficult, and with advancing semiconductor product technology, these plungers gradually become an obstacle to responding to fine pitches.

Moreover, there must be an empty space (gap) between the plungers p1 and p2 inserted inside the barrel 110 and the spring s to allow smooth movement, and the gap must be within an allowable range. In addition, caulking work is required for the plungers p1 and p2 and the barrel 110, and in order to ensure stable electrical connection between the plunger p1 and the barrel 110, and between the barrel 110 and the plunger p2, the diameter tolerance (gap) management for the plungers p1 and p2 and the barrel 110 is need, which makes the assembly process for the production thereof difficult.

Korean Patent No. 10-2046808 discloses bidirectional conductive pins that may be manufactured by stamping without an assembly process, a bidirectional conductive module using the same, and a manufacturing method thereof.

The problem, however, with this case is that because an upper-and-lower contact bar 340 comes into contact along the inner slope of a pin contact part 322, it is expected that there will be difficulty in maintaining stable contact between the pin contact part 322 and the upper-and-lower contact bar 340.

### SUMMARY

Accordingly, the present disclosure has been made keeping in mind the above problems occurring in the related art, and the present disclosure is intended to provide a conductive pin that can be manufactured by stamping without a separate assembly process, and an electronic device test socket equipped with the conductive pin.

In addition, an objective of the present disclosure is to provide a conductive pin that can maintain stable contact during testing of electronic devices, and an electronic device test socket equipped with the conductive pin.

In order to achieve the above objective, according to an embodiment of the present disclosure, there is provided a conductive pin including: a first contact part capable of contacting a first electronic device; a second contact part capable of contacting a second electronic device; a connection part configured to connect the first contact part and the second contact part and to have an empty internal space, and in which at least some sections thereof are elastic; and an extension bar bent from the first contact part and extended through the internal space of the connection part toward the second contact part.

The extension bar may extend, in a cross-sectional view, diagonally from the internal space of the connection part toward the second contact part. When pressure is applied to the first contact part and the second contact part, the extension bar may move toward the second contact part and contact an inner wall surface of the second contact part. The inner wall surface where the extension bar and the second contact part are in contact may be flat.

The connection part may include: a spring section having elasticity; at least one first projection located between the first contact part and the spring section; and at least one second projection located between the second contact part and the spring section. In a side view, the at least one first projection and the at least one second projection may protrude further than the first contact part and the second contact part, respectively.

The second contact part may include: a second body with an empty internal space; a 2-1 tip formed by extending from the second body and capable of contacting the second electronic device; and a 2-2 tip formed by extending from the second body at a position opposite to the 2-1 tip. In a side view, the 2-1 tip and the 2-2 tip may be angled toward each other. In addition, the height of the 2-1 tip may be higher than the height of the 2-2 tip, and an end of the 2-1 tip may be sharp, whereas an end of the 2-2 tip may be blunt.

The second body may include: a second slit penetrating a wall of the second body in a longitudinal direction; and a second window connected to the second slit and penetrating the wall of the second body, but having a wider width than the second slit.

According to a conductive pin, and an electronic device test socket equipped with the same of the present disclosure, manufacturing by stamping is possible without a separate assembly process, and stable contact can be maintained during testing of electronic devices.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view of a pogo pin according to a conventional embodiment;

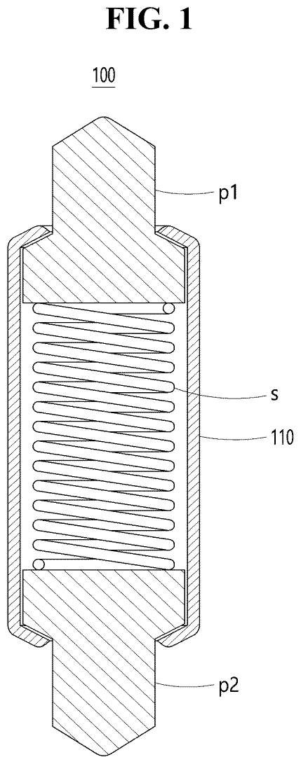

FIG. 2 is a perspective view of a conductive pin according to an embodiment;

FIG. 3 is a cross-sectional view of a conductive pin according to an embodiment;

FIG. 4 is a first side view of a conductive pin according to an embodiment;

FIG. 5 is a second side view of a conductive pin according to an embodiment;

FIG. 6 is a perspective view of a pressed conductive pin according to an embodiment;

FIG. 7 is an enlarged view of a second contact part of a conductive pin according to one embodiment; and

FIG. 8 is a schematic view showing a conductive pin according to an embodiment housed in a housing for an electronic device test socket.

### DETAILED DESCRIPTION

Hereinafter, with reference to the attached drawings, a conductive pin according to an embodiment of the present disclosure and an electronic device test socket equipped with the conductive pin will be described in detail. The following examples of the present disclosure are intended only to concretize the present disclosure and are not intended to limit or restrict the scope of the rights of the present disclosure. It should be interpreted that what can be easily inferred by a specialist in the technical field to which the present disclosure belongs from the detailed description and examples of the present disclosure falls within the scope of the rights of the present disclosure.

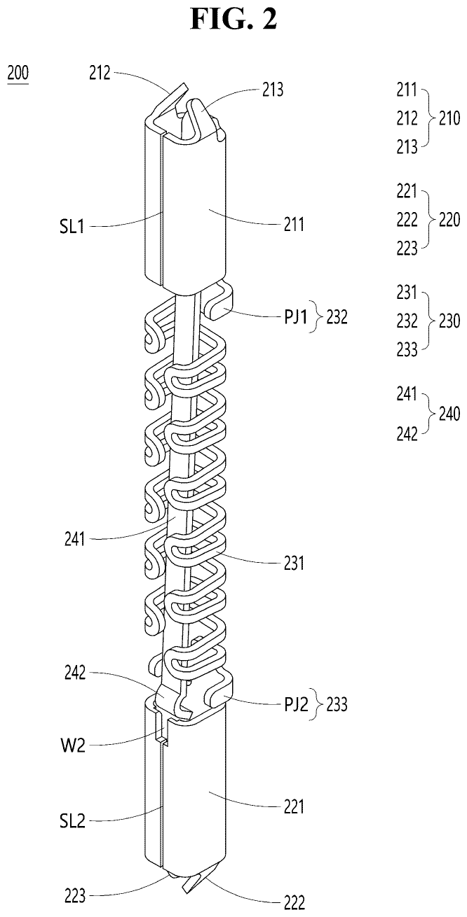

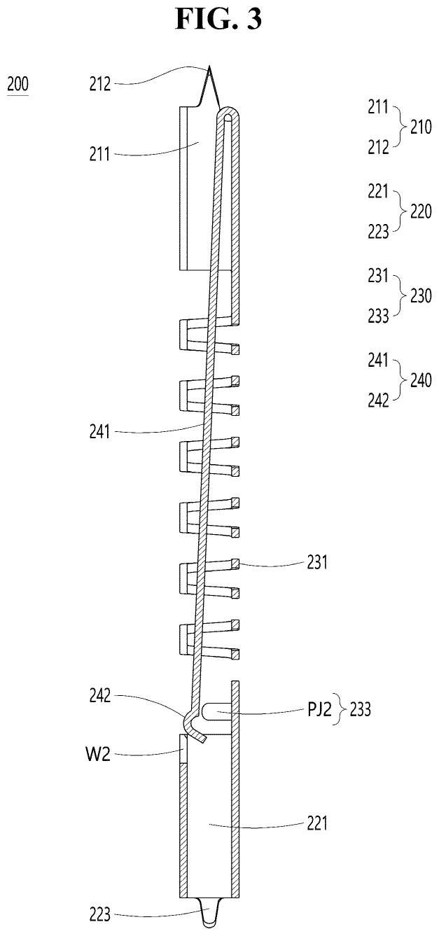

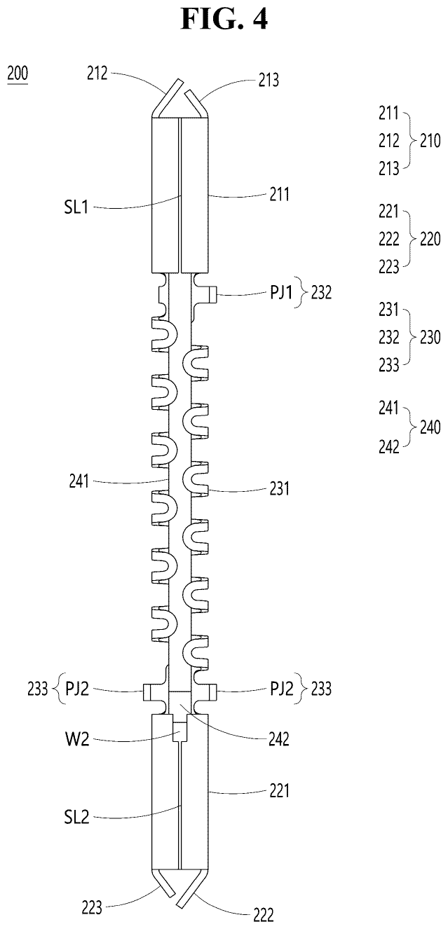

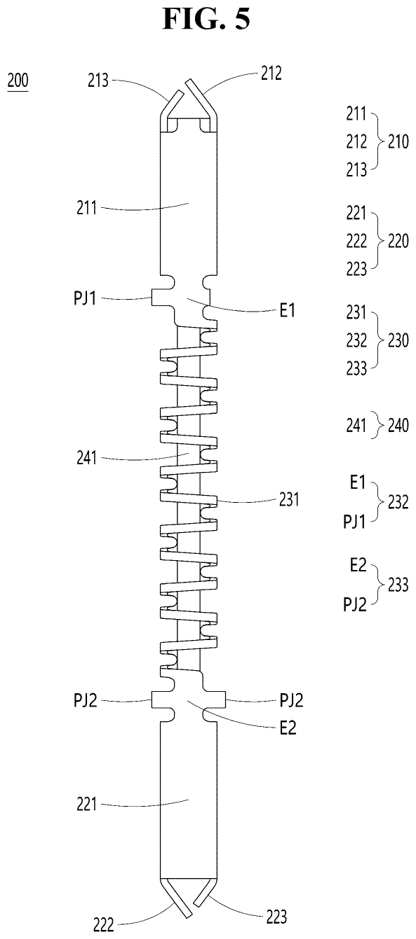

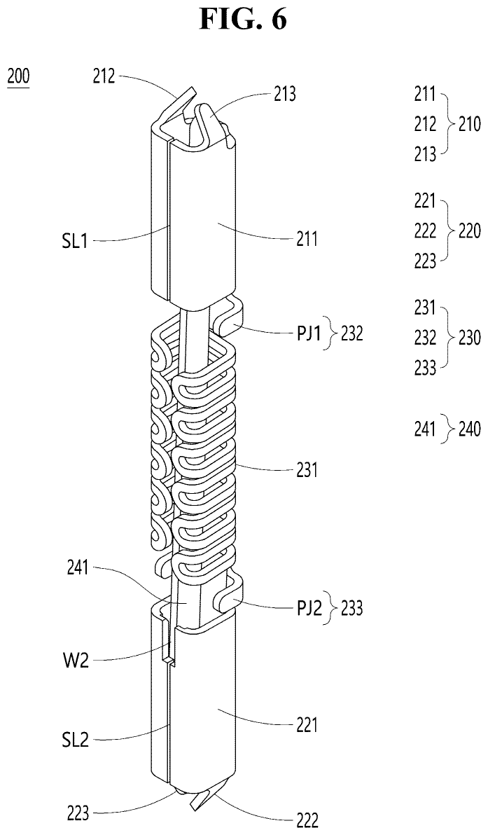

FIGS. 2 to 5 respectively show a perspective view, a cross-sectional view, a first side view, and a second side view of a conductive pin 200 according to one embodiment. In addition, FIG. 6 shows a perspective view of a pressed conductive pin according to an embodiment. For reference, FIG. 2 is a perspective view of a case where no pressure is applied to the conductive pin 200 according to an embodiment.

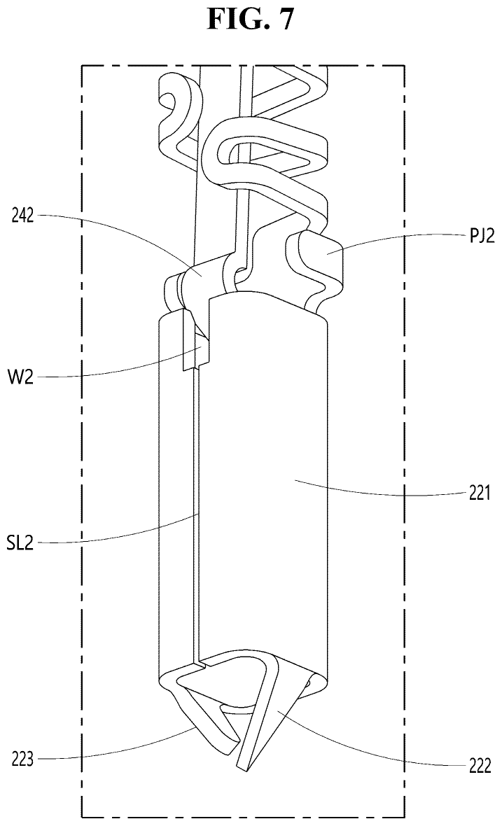

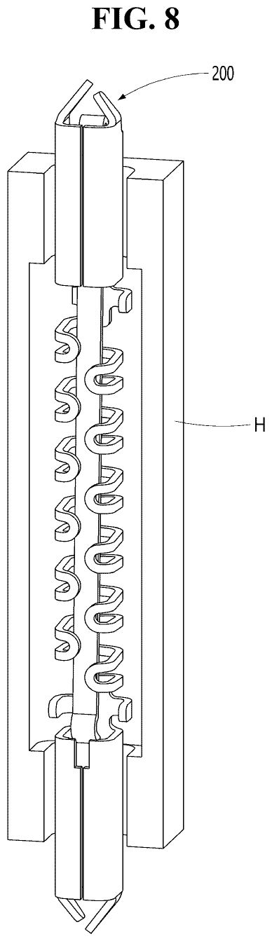

FIG. 7 is an enlarged view of a second contact part 220 of the conductive pin 200 according to an embodiment, and FIG. 8 is an explanatory view of the conductive pin 200 according to an embodiment housed in a housing H for an electronic device test socket.

With reference to FIGS. 2 to 8, the conductive pin 200 according to an embodiment will be described in detail.

The conductive pin 200 according to an embodiment is made by stamping using a single metal plate without a separate assembly process, and may include a first contact part 210, the second contact part 220, a connection part 230, and an extension bar 240.

The first contact part 210 is capable of contacting a first electronic device. In this case, the first electronic device is one of an electronic device, such as a semiconductor device to be tested, or test equipment.

The first contact part 210 includes: a first body 211 having an empty internal space; a 1-1 tip 212 formed by extending from the first body 211 and capable of contacting the first electronic device; and a 1-2 tip 213 formed by extending from the first body 211 at a position opposite to the 1-1 tip 212.

The first body 211 has a first slit SL1 that penetrates the wall surface of the first body 211 in the longitudinal direction. The first body 211 has a hexahedral shape with four walls with gently curved corners, and the upper and lower surfaces of the first body 211 are empty surfaces. In other words, the middle portions of the four walls are flat planes.

It can be seen from the first side view and the second side view that the 1-1 tip 212 and the 1-2 tip 213 are angled toward each other. In addition, the height of the 1-1 tip 212 is higher than that of the 1-2 tip 213, so that only the 1-1 tip 212 comes into contact with the first electronic device during testing. The 1-2 tip 213 serves to maintain the balance of the conductive pin 200. In some cases, the 1-2 tip 213 may serve to support the 1-1 tip 212 when pressure is applied to the 1-1 tip 212.

The end of the 1-1 tip 212 that comes into contact with the first electronic device is sharp, and the end of the 1-2 tip 213 is blunt. That is, the 1-1 tip 212 has a triangular shape, whereas the end of the 1-2 tip 213 has a gently curved shape.

The second contact part 220 has a structure similar to that of the first contact part 210.

To be specific, the second contact part 220 is capable of contacting a second electronic device. In this case, the second electronic device is the other one of an electronic device, such as a semiconductor device to be tested, or test equipment.

The second contact part 220 includes: a second body 221 having an empty internal space; a 2-1 tip 222 formed by extending from the second body 221 and capable of contacting the second electronic device; and a 2-2 tip 223 formed by extending from the second body 221 at a position opposite to the 2-1 tip 222.

The second body 221 has a second slit SL2 that penetrates the wall surface of the second body 221 in the longitudinal direction; and a second window W2 that is connected to the second slit SL2 and penetrates one wall surface of the second body 221, but has a wider width than the second slit SL2. The second body 221 has a hexahedral shape with four walls with gently curved corners, and the upper and lower surfaces of the second body 221 are empty surfaces. That is, the middle portion of each of the four walls is a flat plane. The second window W2 functions as an inlet to allow a plating solution to flow in well during a plating process after the conductive pin 200 is processed into a shape.

It can be seen from the first side view and the second side view that the 2-1 tip 222 and the 2-2 tip 223 are angled toward each other. In addition, the height of the 2-1 tip 222 is higher than that of the 2-2 tip 223, so that only the 2-1 tip 222 comes into contact with the second electronic device during testing. The 2-2 tip 223 serves to maintain the balance of the conductive pin 200. In some cases, the 2-2 tip 223 may serve to support the 2-1 tip 222 when pressure is applied to the 2-1 tip 222.

The end of the 2-1 tip 222 that comes into contact with the second electronic device is sharp, and the end of the 2-2 tip 223 is blunt. That is, the 2-1 tip 222 has a triangular shape, whereas the end of the 2-2 tip 223 has a gently curved shape.

For reference, the 1-1 tip 212 and the 2-1 tip 222 are provided at positions facing each other, and the 1-2 tip 213 and the 2-2 tip 223 are provided at positions facing each other. That is, it can be seen that the 1-1 tip 212 is located on the left side and the 2-1 tip 222 is located on the right side in the first side view. By arranging the tips 212, 213, 222, and 223 in this way, the balance of the conductive pin 200 may be well maintained.

The connection part 230 connects the first contact part 210 and the second contact part 220, has an empty internal space, and at least some sections thereof have elasticity.

To be specific, the connecting part 230 has a spring section 231, a first projection section 232, and a second projection section 233.

The spring section 231 is a spring-shaped section and has elasticity. That is, when the first contact part 210 and the second contact part 220 are pressed during a test, the spring shape is compressed.

The first projection section 232 extends from the first contact part 210 to connect the first contact part 210 and the spring section 231, and has a first extension section E1 and at least one first projection PJ1 positioned between the first contact part 210 and the spring section 231. The width of the first extension section E1 extending from the first contact part 210 is much greater than the thickness of the spring of the spring section 231. In addition, the first projection section 232 may have the first projection PJ1 on at least one of the left and right sides from the first extension section E1 extended from the first contact part 210. For reference, in the conductive pin 200 according to an embodiment, the first projection PJ1 is exemplified as one. The thickness of the first projection PJ1 is also greater than the thickness of the spring of the spring section 231. Additionally, the first projection section 232 is not compressed when the first contact part 210 and the second contact part 220 are pressed. For reference, the thickness of the first projection PJ1 and the thickness of the spring refer to the vertical height on the first side view and the second side view. In addition, the width of the first extension section E1 refers to the horizontal width on the first side view and the second side view.

As can be seen from the first side view and the second side view, at least one first projection PJ1 protrudes further than the spring section 231. For reference, the width of the spring section 231 is the same as the width of the first body 211 or the second body 221. That is, in the first side view and the second side view, at least one first projection PJ1 is shaped to protrude further to the left or right than the first contact part 210 and the second contact part 220.

In addition, each of at least one first projection PJ1 has a width greater than the left or right side of the spring section 231 and is bent in an “¬” shape, but the corner thereof forms a gentle curve.

The second projection section 233 is similar to the first projection section 232.

That is, the second projection section 233 extends from the second contact part 220 to connect the second contact part 220 and the spring section 231, and has a second extension section E2 and at least one second projection PJ2 positioned between the second contact part 220 and the spring section 231. The width of the second extension section E2 extending from the second contact part 220 is much greater than the thickness of the spring of the spring section 231. In addition, second projection section 233 may have the second projection PJ2 on at least one of the left and right sides from the second extension section E2 extended from the second contact part 220. For reference, in the conductive pin 200 according to an embodiment, the second projection PJ2 is exemplified as two. The thickness of the second projection PJ2 is also greater than the thickness of the spring of the spring section 231. Additionally, the second projection section 233 is not compressed when the first contact part 210 and the second contact part 220 are pressed. For reference, the thickness of the second projection PJ2 and the thickness of the spring refer to the vertical height on the first side view and the second side view. In addition, the width of the second extension section E2 refers to the horizontal width on the first side view and the second side view.

As can be seen from the first side view and the second side view, at least one second projection PJ2 protrudes further than the spring section 231. For reference, the width of the spring section 231 is the same as the width of the first body 211 or the second body 221. That is, in the first side view and the second side view, at least one second projection PJ2 is shaped to protrude further to the left or right than the first contact part 210 and the second contact part 220.

In addition, each of at least one second projection PJ2 has a width greater than the left or right side of the spring section 231 and is bent in an “¬” shape, but the corner thereof forms a gentle curve.

Due to at least one first projection PJ1 and at least one second projection PJ2, the conductive pin 200 may be prevented from being escaped from the housing H when inserted into the housing H of the socket and stored.

The extension bar 240 enables a quick and stable electrical connection between the first contact part 210 and the second contact part 220 when pressure is applied to the first contact part 210 and the second contact part 220 during a test.

The extension bar 240 is formed by being bent from the first contact part 210 and extending toward the second contact part 220 through the internal space of the connection part 230. To be specific, the extension bar 240 has a straight section 241 that is bent and connected from the first contact part 210, and a ring section 242 that is connected to the straight section 241 and protrudes in a ring shape at the end of the extension bar 240. The connected portion of the extension bar 240 with the first contact part 210 is not an extended part of the 1-1 tip 212 and the 1-2 tip 213 of the first body 211, but rather one between the extended parts of the 1-1 tip 212 and the 1-2 tip 213.

In a cross-sectional view, the straight section 241 extends diagonally toward the second contact part 220 in the internal space of the connection part 230. In addition, the ring section 242 has a protruding “C” shape compared to the straight section 241.

When pressure is applied to the first contact part 210 and the second contact part 220, the extension bar 240 moves toward the second contact part 220, so that the inner wall surface of the second contact part 220 and the ring section 242 come into contact. The straight section 241 extends diagonally toward the second contact part 220 in the internal space of the connection part 230, and by the protruding ring section 242 at the end, the extension bar 240 may stably maintain contact with the second contact part 220 when pressure is applied to the first contact part 210 and the second contact part 220. Unless pressure is applied to the first contact part 210 and the second contact part 220, the ring section 242 does not come into contact with the second contact part 220.

The extension bar 240 operates in a manner of pushing the inner wall surface of the second contact part 220, and the shape of the angle or width of the diagonal line, the size of the ring section 242, etc. may be changed to adjust the degree of force with which the extension bar 240 pushes the inner wall surface of the second contact part 220. In addition, as can be seen from the cross-sectional view, the width of the extension bar 240 is smaller than the inner diameter of the first body 211 or the second body 221.

In addition, when pressure is applied to the first contact part 210 and the second contact part 220, the inner wall surface where the extension bar 240 and the second contact part 220 come into contact is flat, so that a more wider and stable contact may be maintained with the second contact part 220. That is, by the second body 221 having a flat inner wall surface, the extension bar 240 and the second contact part 220 may come into stable contact over a wide area.

An electronic device test socket according to an embodiment has a number of conductive pins 200 housed in the housing H.

The following summarizes the characteristics of the conductive pin 200 according to an embodiment of the present disclosure and an electronic device test socket equipped with the conductive pin 200.

The extension bar 240 has a slope so as to contact the inner wall surface of the second body 221 of the plane, and is bent in a V-shaped contact bar shape so as to maintain contact with the inner wall surface of the second body 221. In addition, the basic shape of the extension bar 240 before the first contact part 210 and the second contact part 220 are pressed is such that the extension bar 240 does not contact the inner wall surface of the second body 221 to make the plating process easy.

The conductive pin 200 according to an embodiment is formed by shaping a plate material into a spring shape to have tension and then folding the spring-shaped plate material into a square shape. In addition, the first projection section 232 and the second projection section 233 of the upper and lower portions of the spring section 231 are folded to a greater extent than the first contact part 210 and the second contact part 220 to serve as a catch jaw when assembling the conductive pin 200 to the housing H.

The conductive pin 200 according to an embodiment is an integral pin made from a single plate, and since a physical spring is not used, the conductive pin 200 has the connection part 230 having a spring shape from the plate itself to maintain elasticity in the up-down direction. The conductive pin 200 according to an embodiment uses a plate material that is easy to stamp, such as BeCu. In addition, after the shape is realized through stamping, a heat treatment process is performed to increase the strength of the conductive pin 200 and to strengthen the elasticity of the spring. Additionally, after the heat treatment, the conductive pin 200 is subjected to a gold plating process to increase electrical conductivity and corrosion resistance in order to improve the electrical properties of the material and to prevent oxidation during use.

Furthermore, the electronic device test socket according to an embodiment absorbs the mechanical shock transmitted by contact between the first electronic device and the second electronic device and electrically connects the first electronic device and the second electronic device to check for electrical defects.

As described above, according to the conductive pin 200, and the electronic device test socket equipped with the conductive pin 200 of an embodiment, manufacturing by stamping is possible without a separate assembly process, and stable contact may be maintained during testing of electronic devices.

1. A conductive pin, comprising:
a first contact part capable of contacting a first electronic device;
a second contact part capable of contacting a second electronic device;
a connection part configured to connect the first contact part and the second contact part and to have an empty internal space, and in which at least some sections thereof are elastic; and
an extension bar bent from the first contact part and extended through the internal space of the connection part toward the second contact part.

2. The conductive pin of claim 1, wherein the extension bar extends, in a cross-sectional view, diagonally from the internal space of the connection part toward the second contact part.

3. The conductive pin of claim 2, wherein when pressure is applied to the first contact part and the second contact part, the extension bar moves toward the second contact part and contacts an inner wall surface of the second contact part, and the inner wall surface where the extension bar and the second contact part are in contact is flat.

4. The conductive pin of claim 1, wherein the connection part comprises:
a spring section having elasticity;
at least one first projection located between the first contact part and the spring section; and
at least one second projection located between the second contact part and the spring section,
wherein, in a side view, the at least one first projection and the at least one second projection protrude further than the first contact part and the second contact part, respectively.

5. The conductive pin of claim 1, wherein the second contact part comprises:
a second body with an empty internal space;
a 2-1 tip formed by extending from the second body and capable of contacting the second electronic device; and
a 2-2 tip formed by extending from the second body at a position opposite to the 2-1 tip.

6. The conductive pin of claim 5, wherein, in a side view, the 2-1 tip and the 2-2 tip are angled toward each other, and a height of the 2-1 tip is higher than a height of the 2-2 tip.

7. The conductive pin of claim 5, wherein an end of the 2-1 tip is sharp, and an end of the 2-2 tip is blunt.

8. The conductive pin of claim 5, wherein the second body comprises:
a second slit penetrating a wall of the second body in a longitudinal direction; and
a second window connected to the second slit and penetrating the wall of the second body, but having a wider width than the second slit.

9. An electronic device test socket equipped with the conductive pin of claim 1.
